(19) United States
(12) Patent Application Publication
(10) Pub. No.: US 2008/0224266 A1
(43) Pub. Date: Sep. 18, 2008

(54) LATERAL BIPOLAR TRANSISTOR

(75) Inventors: Sheng-Ren Chang, Hsinchu (TW); Hsin Chen, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NATIONAL TSING HUA UNIVERSITY, Hsinchu (TW)

(21) Appl. No.: 12/022,129

(22) Filed: Jan. 29, 2008

(30) Foreign Application Priority Data
Mar. 13, 2007 (TW) 96108817

(51) Int. Cl. H01L 27/00

(52) U.S. Cl. 257/579; 257/E27.015

(57) ABSTRACT

A lateral bipolar transistor is described, including a semiconductor substrate, a gate structure on the substrate, an emitter and a collector of a first conductivity type in the substrate, and a base of a second conductivity type in the substrate. The gate structure has a structure enclosing one or more closed areas. The emitter and the collector respectively includes a plurality of electrically connected unit emitters and a plurality of electrically connected unit collectors defined by the gate structure, which are arranged laterally intermixing with each other and separated by the substrate under the gate structure. The base includes a part under the gate structure.

### CROSS-REFERENCE TO RELATED APPLICATION

This application claims the priority benefit of Taiwan application serial no. 96108817, filed on Mar. 13, 2007. The entirety of the above-mentioned patent application is hereby incorporated by reference herein and made a part of this specification.

### BACKGROUND OF THE INVENTION

1. Field of Invention

This invention relates to a semiconductor device, and more particularly relates to a lateral bipolar transistor of which the fabricating process can be integrated with a CMOS process.

2. Description of Related Art

In integrated circuits, a bipolar junction transistor (BJT) has higher conductance, higher working frequency and lower noise as compared to a MOSFET, and is thus more suitable to analog circuits. The MOSFET needs no gate current and is more suitable to digital circuits than BJT. To make a chip have both BJTs and MOSFETs to improve the flexibility in mixed-signal IC design, the bipolar CMOS (BiCMOS) process was proposed, which is adversely quite complicated. Therefore, a general mixed-signal IC utilizes the parasite BJTs formed in a standard CMOS process to lower the cost.

FIG. 1A illustrates a layout of a prior-art lateral BJT adopted in a standard CMOS process, and FIG. 1B is its cross-sectional view along the line I-I′. Referring to FIGS. 1A and 1B, the lateral BJT includes a P-type (or N-type) substrate 100, a heavily doped substrate pickup 102 in the substrate 100, a base 110 as an N-well (or P-well) in the substrate 100, a heavily doped well pickup 112 in the well 110 near the edge of the same, an emitter 120 as a P-doped (or N-doped) region in the well 110, a collector 130 as a P-doped (or N-doped) region in the well 110, and a gate structure 144 including gate dielectric 142 and a gate 140 on the well 110 between the emitter 120 and collector 130. The gate 140 serves as a mask when the emitter 120 and collector 130 are being defined. The substrate pickup 102, the well pickup 112, the emitter 120 and the collector 130 are connected to different pars of the first interconnect layer 160 via contact plugs 150.

Referring to FIG. 1B, the efficiency of such a BJT is defined as the percentage of the minor carriers entering the collector 130 as a collector current in total minor carriers injected in the base 110 from the emitter 120. To improve the efficiency, the efficiency of the collector 130 collecting the minor carriers injected in the base 110 is usually increased by forming the gate 140 in the minimal linewidth of the process to decrease the distance between the emitter 120 and collector 130 and by making the collector 130 surround the emitter 120. The rated current of the BJT is positively proportional to the lateral facing area between the emitter 120 and the base 110. To increase the rated current, a prior-art method is to connect a plurality of such BJTs in parallel, as shown in FIG. 1C, wherein five such BJTs are connected in parallel via their bases 110.

However, in the above structure, there is also a parasite vertical BJT including the emitter 120, the base 110 and the substrate 100. Hence, a part of the minor carriers injected to the base 110 enter the substrate 100 decreasing the efficiency of the lateral BJT, and the current flowing into the substrate 100 becomes the noise of other circuits and raises the electricity consumption. The relationship between the current I_{E} of the minor carriers injected into the base 110, the current I_{C} of the collector 130, the current I_{B} of the base 110 and the current I_{S} of the substrate 100 is expressed by Eq. (1):

[symbol]

·I_{E}=I_{C}+I_{B}+I_{S} (1)

The above conventional lateral BJT can merely have an efficiency (=I_{C}/I_{E}) of 0.64.

### SUMMARY OF THE INVENTION

Accordingly, this invention provides a lateral bipolar transistor that has a higher efficiency and has a larger lateral facing area between the emitter and the base in a given device area to increase the rated current of the bipolar transistor.

The lateral bipolar transistor includes a semiconductor substrate, a gate structure on the substrate, an emitter and a collector of a first conductivity type in the substrate, and a base of a second conductivity type in the substrate. The gate structure encloses one or more closed areas. The emitter and the collector respectively include a plurality of electrically connected unit emitters and a plurality of electrically connected unit collectors defined by the gate structure, which are arranged laterally intermixing with each other and are separated by the substrate under the gate structure. The base includes a first part under the gate structure.

In some embodiments, one of the plurality of unit emitters and the plurality of unit collectors are separated from each other in the substrate and are electrical connected via a part of at least one interconnect layer. In an embodiment, the one of the plurality of unit emitters and the plurality of unit collectors are electrically connected via a part of a first interconnect layer, and the other of the plurality of unit emitters and the plurality of unit collectors are connected in the substrate by a doped region of the first conductivity type as a part of the collector. In another embodiment, the one of the plurality of unit emitters and the plurality of unit collectors are electrically connected via a part of a first interconnect layer, and the other of the plurality of unit emitters and the plurality of unit collectors are electrically connected via another part of the first interconnect layer and a doped region of the first conductivity type as a part of the collector. In still another embodiment, the one of the plurality of unit emitters and the plurality of unit collectors are electrically connected via a part of a first interconnect layer and a part of a second interconnect layer over the first interconnect layer, and the other of the plurality of unit emitters and the plurality of unit collectors are electrically connected via another part of the first interconnect layer and a doped region of the first conductivity type as a part of the collector.

In some embodiments, any of the plurality of unit emitters and the plurality of unit collectors are connected in the substrate via one or more doped regions of the first conductivity type as a part or parts of the emitter or the collector.

In some embodiments, the substrate has the first conductivity type, the base includes a well of the second conductivity type in the substrate, and the emitter and the collector are located in the well. The collector may also include a part surrounding the unit emitters and the unit collectors, which is separated from the unit emitters by the substrate under the gate structure and is electrically connected with the unit collectors.

Since the emitter and the collector respectively include unit emitters and unit collectors arranged laterally intermixing with each other, the lateral facing area between the emitter and the collector is increased improving the efficiency of the transistor and that between the emitter and the base is also increased enlarging the rated current.

In order to make the aforementioned and other objects, features and advantages of the present invention comprehensible, a preferred embodiment accompanied with figures is described in detail below.

### BRIEF DESCRIPTION OF THE DRAWINGS

FIG. 1A illustrates a layout of a prior-art bipolar transistor adopted in a standard CMOS process, FIG. 1B is its cross-sectional view along line I-I′, and FIG. 1C shows a bipolar transistor device including five such bipolar transistors connected in parallel.

FIG. 2A illustrates a layout of lateral bipolar transistor in an example of a first embodiment of this invention where the unit emitters are separated in the substrate but electrically connected via at least one interconnect layer, wherein the emitter is divided into five unit emitters, and FIG. 2B is its cross-sectional view along line II-II′.

FIG. 3 illustrates a layout of lateral bipolar transistor in another example of the first embodiment with the emitter divided into 25 unit emitters by the gate structure.

FIG. 4 illustrates a layout of bipolar transistor in still another example of the first embodiment with the emitter divided into 61 unit emitters by the gate structure.

FIG. 5 illustrates a layout of lateral bipolar transistor in an example of a second embodiment of this invention where the unit emitters are connected in the substrate via a number of doped regions of the same conductivity type.

FIG. 6 shows respective V_{BE}-I curves of the emitter, the collector, the base and the substrate when a prior-art lateral BJT as shown in FIG. 1A is being operated.

FIG. 7 shows respective V_{BE}-I curves of the emitter, the collector, the base and the substrate when a lateral BJT of this invention as shown in FIG. 2A is being operated.

### DESCRIPTION OF EMBODIMENTS

In the following embodiments, the substrate of the lateral bipolar transistor has a conductivity type different from that of the base of the lateral bipolar transistor, the base includes a well, and the emitter and the collector are located in the well; meanwhile, the collector also includes a part surrounding the unit emitters and unit collectors, separated from the unit emitters by the substrate under the gate and electrically connected with the unit collectors. However, this invention is not limited to the above configuration.

### First Embodiment

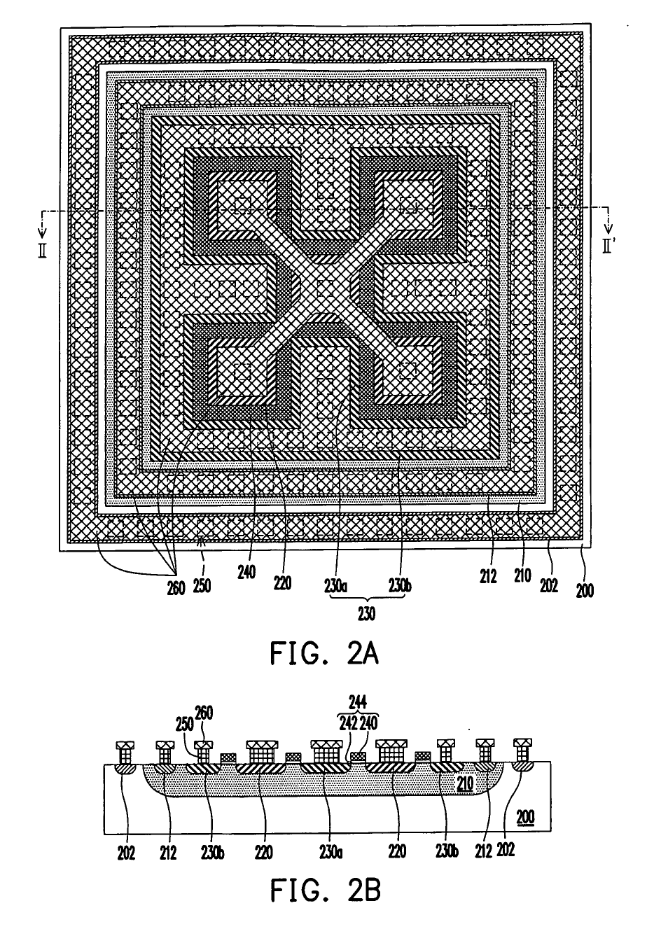

FIG. 2A illustrates a layout of lateral bipolar transistor in an example of a first embodiment of this invention where the unit emitters are separated in the substrate but are electrically connected via at least one interconnect layer, and FIG. 2B is its cross-sectional view along line II-II′.

Referring to FIGS. 2A and 2B, the bipolar transistor includes a P-type (or N-type) substrate 200, a heavily doped substrate pickup region 202 in the substrate 200, a base 210 as an N-well (or P-well) in the substrate 200, a heavily doped well pickup region 212 in the well 210 near the edge of the same, a gate structure 244 that includes a gate dielectric layer 242 and a gate conductor 240 thereon and encloses five closed areas on the well 210, a P-type (or N-type) emitter in the well 210 divided into five unit emitters 220 by the gate structure 244, and a P-type (or N-type) collector 230 in the well 210. The unit emitters 220 and the collector 230 are generally formed simultaneously in an ion implantation process using the gate structure 244 and a patterned photoresist layer (not shown) as a mask and therefore have the same dopant concentration.

The substrate 200 may include lightly P- or N-doped single-crystal silicon. The substrate pickup region 202 may have an annular shape that encloses the base 210, and the well pickup region 212 may have an annular shape that encloses the collector 230. The five unit emitters 220 separated from each other in the well 210 are electrically connected with each other via a number of contact plugs 250 thereon and a part of the first interconnect layer 260 spreading to the respective unit emitters 220. The collector 230 includes four unit collectors 230a each partially surrounded by a part of the gate structure 244 and arranged laterally intermixing with the unit emitters 220, and a doped region 230b surrounding the unit emitters 220 and the unit collectors 23oa, separated from the unit emitters 220 by the substrate 200 under another part of the gate structure 244 and connected with the unit emitters 230a in the well 210.

In addition, the substrate pickup region 202, the well pickup region 212, the unit emitters 220, and the collector 230 including the unit collectors 230a and a surrounding part 230b, are respectively connected to different parts of the first interconnect layer 260 via many contact plugs 250. The contact plugs 250 may have substantially the same lateral size, and the first interconnect layer 260 may include a metal. The linewidth of the first interconnect layer 260 is designed such that the interconnect lines can sustain the maximum current required in the operation of the lateral bipolar transistor.

Moreover, though the gate structure 244 includes orthogonal grid lines so that each unit emitter 220 has a substantially square shape in the above embodiment, the shape of the gate structure 244 can be altered to make a unit emitter have a substantially rectangular shape, a substantially circular shape, a substantially polygonal shape or the like. The linewidth of the gate conductor 240 is preferably the minimum linewidth in the fabricating process, so as to reduce the base width of the transistor and increase the efficiency thereof. The gate conductor 240 may include doped poly-Si, and the gate dielectric layer 242 may include SiO₂ or a high-k material like zirconium oxide, TaO₂, hafnium oxide or hafnium silicon oxide. Further, the P-type parts of the above bipolar transistor may be doped with boron while the N-type parts doped with phosphorous.

Moreover, in the layout design stage before the fabricating process, the above parts of the lateral BJT are usually defined in the order of the gate conductor 240, the substrate pickup region 202 and the active area containing the unit emitters 220 and the collector 230, the base/well 210, the well pickup region 212, the contact plugs 250 and the first interconnect layer 260. The unit emitters 220, the unit collectors 230a and the surrounding part 230b of the collector 230 are automatically defined when the layouts of the gate conductor 240 and the active area are defined.

Since each unit emitter 220 is surrounded by two unit collectors 230a and the part 230b of the collector 230 and shares two or all unit collectors 230a with the other unit emitters 220, the efficiency of the lateral bipolar transistor is improved.

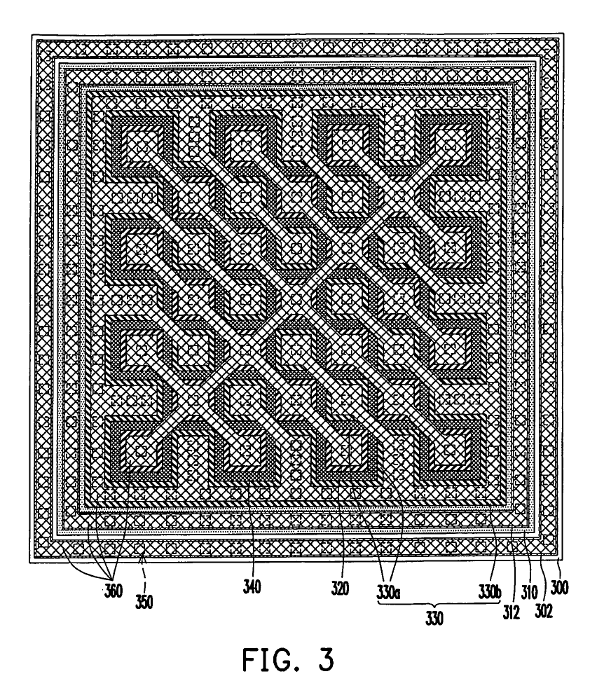

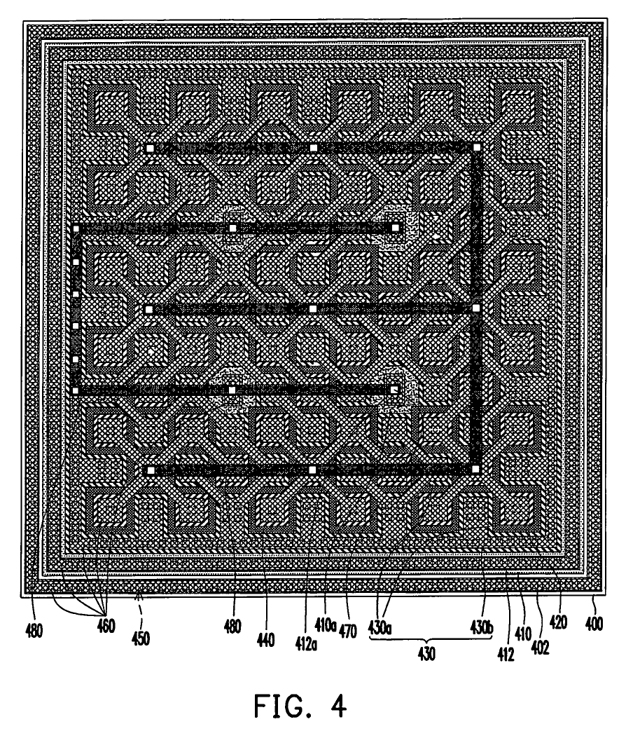

Further, to increase the rated operation current of the lateral BJT, the number of the unit emitters 220 can be increased, possibly by connecting several above BJTs in parallel or by altering the shape of the gate structure 244 to divide the emitter to more unit emitters. For example, the emitter can be divided into 25 unit emitters, as shown in FIG. 3. It is also noted that when there are more unit emitters, such as 61 emitters as shown in FIG. 4, current distribution uniformity of the base occurs due to the resistance of the base. To solve the uniformity issue, the base may further include a part between several unit emitters and between several unit collectors that is contiguous with the part of the base under the gate structure and has a heavily doped pickup region therein.

FIG. 3 illustrates a layout of lateral bipolar transistor in another example of the first embodiment of this invention, wherein the emitter is divided into 25 unit emitters by the gate structure.

In this example, the substrate 300, the substrate pickup region 302, the base/well 310, the well pickup region 312 respectively may have the same features of the parts 200, 202, 210 and 212 in the above example, and the collector 330 still includes a part (doped region) 330b surrounding the unit emitters 320 and the unit collectors 330a like the collector 230 does.

However, the gate structure 340 includes more orthogonal grid lines to enclose more (37) closed areas, and the emitter is divided by the gate structure 340 into 25 unit emitters 320 located in 25 closed areas and separated from each other in the well 310. Meanwhile, though the collector 330 still includes a part 330b surrounding the unit emitters 320 and the unit collectors 330a as in the case of the collector 230, some of the unit collectors 330a are located in the remaining closed areas and separated from each other and also separated from the outer unit collectors 330a in the well 310. Therefore, certain interconnect lines and corresponding contact plugs are required for the electrical connection of any of the unit emitters 320 and the unit collectors 330a.

More specifically, the 25 unit emitters separated from each other in the well 310 are electrically connected with each other via a part of the first interconnect layer 360 and corresponding contact plugs 350 therebetween. Meanwhile, the 12 unit collectors 330a separated from each other and also from the outer unit collectors 330a in the well 310 are electrically connected with each other and with the outer unit collectors 330a via another part of the interconnect layer 360. In addition, the substrate pickup region 302 and the well pickup region 312 are respectively connected to other parts of the first interconnect layer 360 via numerous contact plugs 350.

FIG. 4 illustrates a layout of lateral bipolar transistor in still another example of the first embodiment of this invention, wherein the emitter is divided into 61 unit emitters by the gate structure.

In this example, the substrate 400, the substrate pickup region 402, the base/well 410, the well pickup region 412 may respectively have the same features of the parts 300, 302, 310 and 312 in the above example, and the collector 430 still includes a part (doped region) 430b surrounding the unit emitters 420 and the unit collectors 430a like the collector 330 does.

However, the gate structure 440 includes more orthogonal grid lines to enclose more closed areas, and the emitter is divided by the gate structure 440 into 61 unit emitters located in 61 closed areas and separated from each other in the well 410. Meanwhile, more unit collectors 430a are defined by the gate structure 440, including some partially surrounded by the gate structure 440 and some in the remaining closed areas enclosed by the gate structure 440, wherein the latter unit collectors 430a are electrically connected with each other and with the outer unit collectors 430a via a part of the first interconnect layer 460 and corresponding contact plugs 450.

Since there are so many unit collectors 430a need to be electrically connected via a part of the first interconnect layer 460, not only another part of the first interconnect layer 460 and corresponding contact plugs 450 but also a part of the second interconnect layer 480 and corresponding via plugs 470 are required for the electrical connection of the 61 unit emitters 420 that are separated from each other in the well 410, as shown in FIG. 4. The first interconnect layer 460 and the second interconnect layer 480 may both include metal. The linewidths of the first interconnect layer 460 and the second interconnect layer 460 are designed such that the interconnect lines can sustain the maximum current required in the operation of the lateral bipolar transistor.

Moreover, to prevent current distribution uniformity in the base 410 due to the resistance of the same, the base 410 may further include certain parts 410a between several unit emitters 420 and between several unit collectors 430a, each of which is contiguous with the part of the base 410 under the gate structure 440 and has a heavily doped pickup region 412a therein. Each pickup region 412a is electrically connected to another part of the second interconnect layer 480 via at least one contact plug 450, a small part of the first interconnect layer 460 and at least one via plug 470. The part of the first interconnect layer 460 connected with the well pickup region 412 via certain contact plugs 450 may also be electrically connected with the “another” part of the second interconnect layer 480 via certain via plugs 470, as shown in FIG. 4.

### Second Embodiment

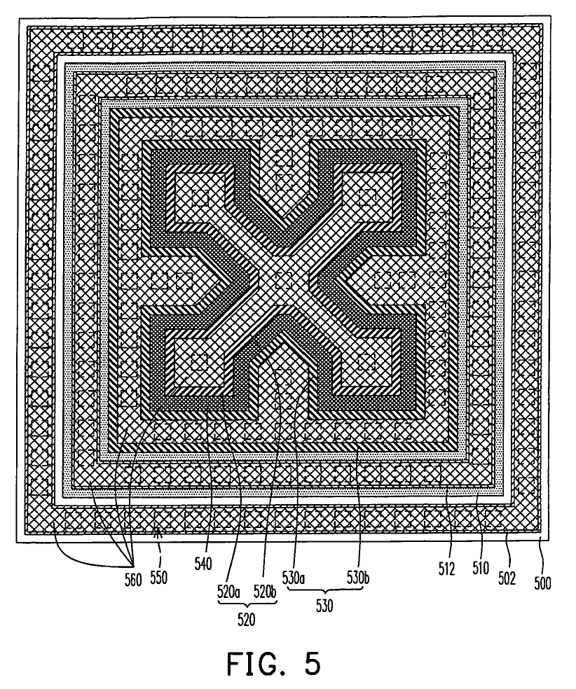

FIG. 5 illustrates a layout of lateral bipolar transistor in an example of a second embodiment of this invention where the unit emitters are connected in the substrate via a number of doped regions of the same conductivity type.

In this example, the substrate 500, the substrate pickup region 502, the base/well 510, the well pickup region 512 may respectively have the same features of the parts 200, 202, 210 and 212 in the first example of the first embodiment, and, similar to the case of the collector 230, the collector 530 still includes several unit collectors 530a that are partially surrounded by the gate structure 540 and are connected with each other in the well 510 via a part (doped region) 530b surrounding the unit emitters 520 and the unit collectors 530a.

However, the gate structure 540 merely enclose one closed area that may be considered to have “pore” parts and channel parts, and the unit emitters 520a are not only connected with a part of the first interconnect layer 560 via certain contact plug 550 but also connected with each other in the well 510 via several doped regions 520b of the same conductivity between them. The unit emitters 520a and the doped regions 520b together constitute an emitter 520.

### Experiments

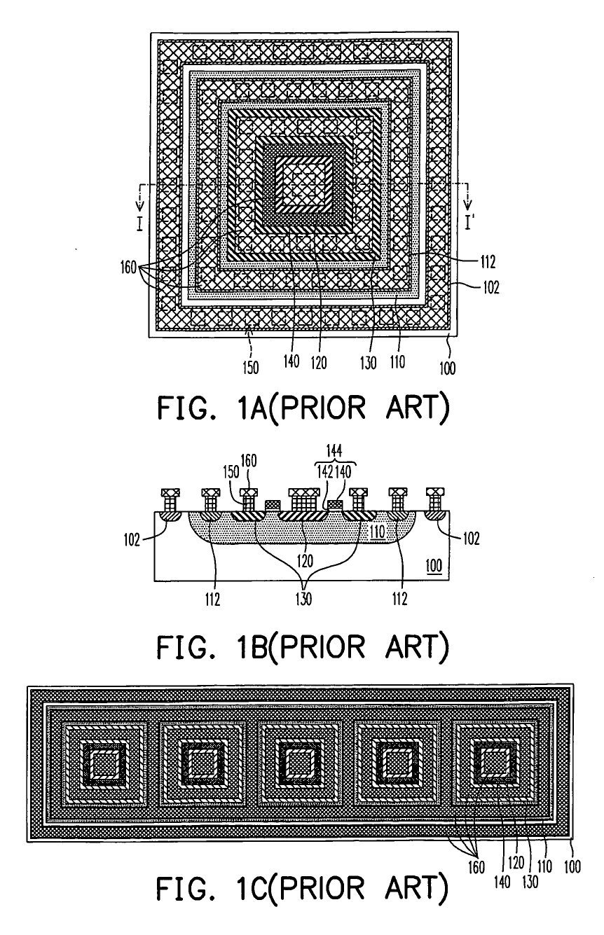

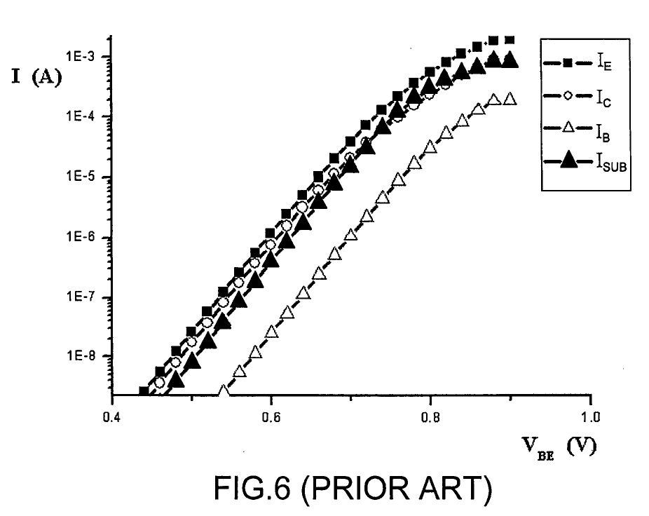

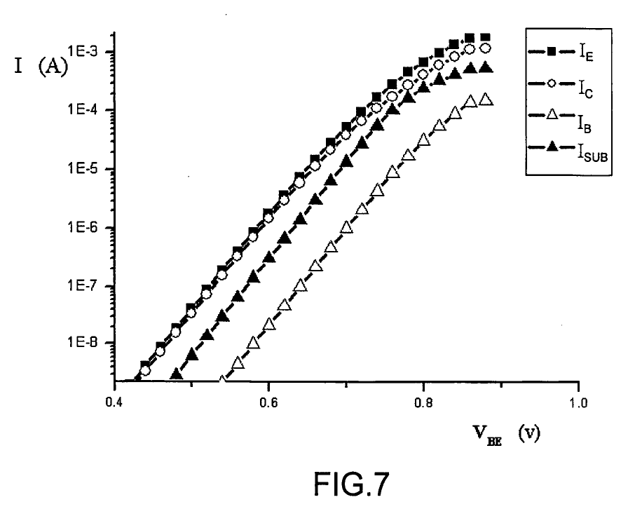

A lateral bipolar transistor fabricated according to the layout of FIG. 2A has been tested, and the test result is shown in Table 1 and FIG. 7 that shows respective V_{BE}-I curves of the emitter, the collector, the base and the substrate. Respective V_{BE}-I curves of the emitter, the collector, the base and the substrate of a prior-art lateral bipolar transistor as shown in FIG. 1A is also shown in FIG. 6 for comparison.

As usual, in the operation test of the bipolar transistor, the bias of the gate 140/240 relative to the base 110/210 was set not causing an inversion layer in the latter, the emitter 120/220 was applied with a forward bias relative to the base 110/210, the collector 130/230 applied with a reverse bias relative to the base 110/210 and the base 110/210 applied with a reverse bias relative to the substrate 100/200.

TABLE 1

| | I_{C}/I_{E} | I_{B}/I_{E} | I_{Sub}/I_{E} |
|---|---|---|---|
| Conventional layout | 0.64 | 0.02 | 0.34 |
| 2D-intermixing layout | 0.84 | 0.01 | 0.15 |

Since each unit emitter 220 not only is adjacent to the unit collectors 230a and the doped region 230b around but also shares other unit collectors 230a with other unit emitters 220, the minor carriers injected into the base 210 from the unit emitters 220 have higher probability to enter the collector 230 so that the efficiency (IC/IE) of the lateral bipolar transistor can be raised up to about 0.84. By further increasing the number of the unit emitters as shown in FIGS. 3 and 4, the emitter-base facing area and the emitter-collector facing area both can be further increased to further improve the rated operation current and the efficiency of the lateral bipolar transistor.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A lateral bipolar transistor, comprising:
a semiconductor substrate;
a gate structure on the substrate, enclosing one or more closed areas;
an emitter and a collector of a first conductivity type in the substrate, respectively including a plurality of electrically connected unit emitters and a plurality of electrically connected unit collectors defined by the gate structure, wherein the plurality of unit emitters and the plurality of unit collectors are arranged laterally intermixing with each other and separated by the substrate under the gate structure; and
a base of a second conductivity type in the substrate, including a first part under the gate structure.

2. The lateral bipolar transistor of claim 1, wherein one of the plurality of unit emitters and the plurality of unit collectors are separated from each other in the substrate and are electrically connected via a part of at least one interconnect layer.

3. The lateral bipolar transistor of claim 2, wherein the one of the plurality of unit emitters and the plurality of unit collectors are electrically connected via a part of a first interconnect layer, and the other of the plurality of unit emitters and the plurality of unit collectors are connected in the substrate by a doped region of the first conductivity type as a part of the collector.

4. The lateral bipolar transistor of claim 2, wherein the one of the plurality of unit emitters and the plurality of unit collectors are electrically connected via a part of a first interconnect layer, and the other of the plurality of unit emitters and the plurality of unit collectors are electrically connected via another part of the first interconnect layer and a doped region of the first conductivity type as a part of the collector.

5. The lateral bipolar transistor of claim 2, wherein the one of the plurality of unit emitters and the plurality of unit collectors are electrically connected via a part of a first interconnect layer and a part of a second interconnect layer over the first interconnect layer, and the other of the plurality of unit emitters and the plurality of unit collectors are electrically connected via another part of the first interconnect layer and a doped region of the first conductivity type as a part of the collector.

6. The lateral bipolar transistor of claim 1, wherein any of the plurality of unit emitters and the plurality of unit collectors are connected in the substrate via one or more doped regions of the first conductivity type as a part or parts of the emitter or the collector.

7. The lateral bipolar transistor of claim 1, wherein the base further includes a second part between a number of unit emitters and between a number of unit collectors, wherein the second part of the base is contiguous with the first part of the base under the gate structure and has a pickup region therein.

8. The lateral bipolar transistor of claim 1, wherein either each unit emitter or each unit collector has a substantially square shape, a substantially rectangular shape, a substantially circular shape or a substantially polygonal shape.

9. The lateral bipolar transistor of claim 1, wherein the substrate has the first conductivity type, the base comprises a well of the second conductivity type in the substrate, and the emitter and the collector are located in the well.

10. The lateral bipolar transistor of claim 9, wherein the collector further comprises a part surrounding the unit emitters and the unit collectors, separated from the unit emitters by the substrate under the gate structure and electrically connected with the unit collectors.

11. The lateral bipolar transistor of claim 10, wherein all of the unit emitters are separated from each other in the well and are electrically connected via a part of at least one interconnect layer.

12. The lateral bipolar transistor of claim 11, wherein the unit emitters are electrically connected via a part of a first interconnect layer, and the unit collectors are directly connected with the part of the collector in the well.

13. The lateral bipolar transistor of claim 11, wherein the unit emitters are electrically connected via a part of a first interconnect layer, and the unit collectors are electrically connected via another part of the first interconnect layer and the part of the collector.

14. The lateral bipolar transistor of claim 11, wherein the unit emitters are electrically connected via a part of a first interconnect layer and a part of a second interconnect layer over the first interconnect layer, and the unit collectors are electrically connected via another part of the first interconnect layer and the part of the collector.

15. The lateral bipolar transistor of claim 10, wherein the unit emitters are connected in the well via doped regions of the first conductivity type.

16. The lateral bipolar transistor of claim 10, wherein the base further includes a second part between a number of unit emitters and between a number of unit collectors that is contiguous with the first part of the base and has a pickup region therein.

17. The lateral bipolar transistor of claim 10, wherein each unit emitter has a substantially square shape, a substantially rectangular shape, a substantially circular shape or a substantially polygonal shape.

18. The lateral bipolar transistor of claim 1, wherein the gate structure comprises a gate dielectric layer and a gate conductor on the gate dielectric layer.

19. The lateral bipolar transistor of claim 18, wherein a linewidth of the gate conductor is equal to or larger than a minimum linewidth of a semiconductor process for fabricating the lateral bipolar transistor.

20. The lateral bipolar transistor of claim 18, wherein the gate dielectric layer comprises SiO₂, zirconium oxide, TaO₂, hafnium oxide or hafnium silicon oxide.

21. The lateral bipolar transistor of claim 1, wherein the base, the unit emitters and the unit collectors are electrically connected to different parts of an interconnect layer via a plurality of contact plugs having substantially the same lateral size.
